(19) United States
(12) Patent Application Publication
(10) Pub. No.: US 2002/0125545 A1
(43) Pub. Date: Sep. 12, 2002

(54) Spherical semiconductor device containing two or more spherical semiconductors combined together

(75) Inventors: Shiro Kano, Tokyo (JP); Ikuo Nishimoto, Tokyo (JP); Shigeo Miyagawa, Tokyo (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Yamatake Corporation, Shibuya-ku (JP)

(21) Appl. No.: 09/997,064

(22) Filed: Nov. 29, 2001

(30) Foreign Application Priority Data
Dec. 1, 2000 (JP) 2000-367069

(51) Int. Cl. H01L 21/8222; H01L 29/00

(52) U.S. Cl. 257/528; 438/329; 257/531; 257/532

(57) ABSTRACT

A spherical semiconductor device 1a comprises three spherical semiconductors 10, 20 and 30, which are connected together. An electronic circuit is formed on the surface of the central spherical semiconductor 10, among the three spherical semiconductors, while a coil 21 and a capacitor 31 are formed on the respective surfaces of the other spherical semiconductors 20 and 30, respectively. Since the spherical semiconductors 20 and 30 at the opposite ends are independent of the central spherical semiconductor 10, an insulating film on the coil 21 never influences the properties of the electronic circuit of the central spherical semiconductor 10, and the capacitor 31 can secure a capacity large enough to maintain satisfactory operating power for the spherical semiconductor device 1a. Since the three spherical semiconductors 10, 20 and 30 are manufactured in different processes, moreover, the productivity of the spherical semiconductors cannot be lowered by differences between manufacturing processes.

### BACKGROUND OF THE INVENTION

1. Field of the Invention

The present invention relates to a spherical semiconductor device having an electronic circuit formed on the surface of a spherical semiconductor, and more particularly, to a spherical semiconductor device containing two or more spherical semiconductors combined together.

2. Description of the Related Art

A spherical semiconductor device has an electronic circuit that performs specific processing functions. The electronic circuit is formed integrated on the surface of a spherical semiconductor. Further, the spherical semiconductor device can transmit an output from the electronic circuit, that is, the result of its processing, to an external apparatus by radio communication. Necessary DC power for the actuation of the electronic circuit to perform its functions and for the radio communication is supplied by utilizing RF(Radio Frequency) carrier wave that is radiated from the external apparatus by means of electromagnetic induction. The spherical semiconductor device has a coil and a regulator, which are formed on the surface of the spherical semiconductor. The coil is connected to the regulator, which can receive the RF carrier wave energy through the coil and rectify the current induced in the coil to produce DC voltage.

The coil is also used as a communication antenna. The spherical semiconductor device includes a communication circuit, which is formed on the surface of the spherical semiconductor. The coil is also connected to the communication circuit, which transmits the output of the electronic circuit to the external apparatus through the coil.

In the case where the electronic circuit and the coil are formed together on one spherical semiconductor, they should be securely insulated from each other. This is because the coil is formed as a wiring pattern of aluminum or copper with several turns on the surface of the spherical semiconductor. Therefore, a series of processes of manufacturing the spherical semiconductor device includes a step of stacking the electronic circuit on the surface of the spherical semiconductor, a step of forming an insulating film (oxide film) on the electronic circuit to cover the electronic circuit, and a step of forming the coil on the insulating film. When the spherical semiconductor device is manufactured undergoing these steps, the insulation between the electronic circuit and the coil is secured satisfactorily. If the insulating film is made too thick, however, it influences the properties of the electronic circuit.

In some cases, a memory circuit may be incorporated in the electronic circuit of the spherical semiconductor device, on which the electronic circuit and the coil are formed together. Incorporating the memory circuit into the electronic circuit requires addition of a dedicated manufacturing process.

In some cases, moreover, the spherical semiconductor device may be formed having passive elements such as a capacitor and a resistor, besides the aforesaid coil. The larger or higher the capacitance or resistance value of these passive elements, the wider the area on the surface of the spherical semiconductor occupied by the passive elements is. Since the passive elements occupy the wider region on the surface of the one spherical semiconductor, the region on which the electronic circuit is formed is narrowed correspondingly.

### SUMMARY OF THE INVENTION

The present invention disclosed and claimed herein, in one aspect thereof, comprises a spherical semiconductor device containing two or more spherical semiconductors combined together. One spherical semiconductor has an electronic circuit, while the other spherical semiconductor has a coil. These two spherical semiconductors are bonded to each other by means of an electrode terminal. The electrode terminal also electrically connects the electronic circuit and the coil between the two spherical semiconductors. The electronic circuit includes a power supply unit. If RF carrier wave energy is radiated from an external apparatus and applied to the spherical semiconductor device, the power supply unit can receive it through the coil and rectify the current induced in the coil to produce a voltage for the actuation of the electronic circuit.

A manufacturing process for the spherical semiconductor device is simple. The one spherical semiconductor that has the electronic circuit is manufactured in a conventional spherical semiconductor process. The other spherical semiconductor that has the coil is manufactured by utilizing the technique of another conventional semiconductor process. The specific contents of these two processes are different, and both these processes are simple. The spherical semiconductor device is obtained by bonding the two spherical semiconductors by means of the electrode terminal.

Two or more spherical semiconductors may be arranged so that one of them has an electronic circuit, while the others have a circuit element each. The circuit element used can perform at least one of the respective functions of a capacitor, resistor, sensor, and memory. In this case also, the two spherical semiconductors are connected to each other by means of the electrode terminal, and the electronic circuit and the circuit element are connected electrically to each other by means of the electrode terminal.

Further scope of applicability of the present invention will become apparent from the ensuing detailed description. However, it should be understood that the detailed description and specific example, while indicating preferred embodiment of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinafter and the accompany drawings which are given by way of illustration only, and thus, are not limitative of the present invention, and wherein:

FIG. 1 is an outside view of a spherical semiconductor device according to a first embodiment;

FIG. 2 is an outside view of a spherical semiconductor having a coil formed on its surface;

FIG. 3 is a diagram showing a circuit configuration of the spherical semiconductor device according to the first embodiment;

FIG. 4 is a diagram showing a circuit configuration of a spherical semiconductor device according to a second embodiment;

FIG. 5 is an outside view of the spherical semiconductor device according to the second embodiment;

FIG. 6 is a diagram showing a circuit configuration of a spherical semiconductor device according to a third embodiment; and

FIG. 7 is an outside view of a spherical semiconductor having three coils formed on its surface.

### DETAILED DESCRIPTION

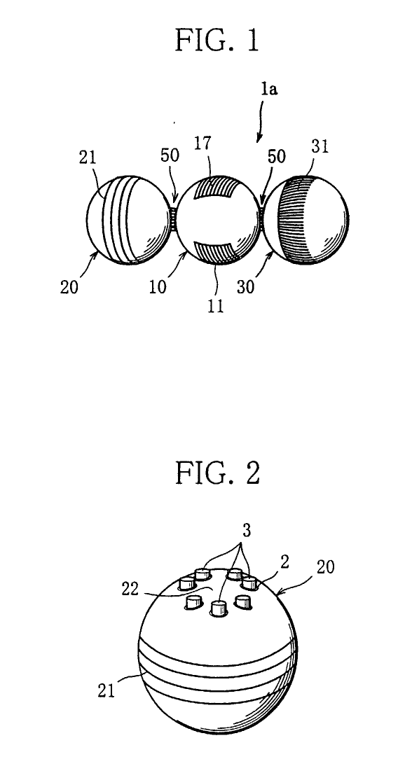

FIG. 1 shows a spherical semiconductor device 1a according to a first embodiment. The spherical semiconductor device 1a operates in an environment that involves RF carrier wave energy. The RF carrier wave energy is radiated from an external apparatus (not shown) by means of electromagnetic induction.

As shown in FIG. 1, the spherical semiconductor device la comprises three spherical semiconductors 10, 20 and 30 that are combined together. Each of the spherical semiconductors 10, 20 and 30 is formed of a silicon sphere with a diameter of about 1 mm, for example. An electronic circuit having specific processing functions is formed on the surface of the one spherical semiconductor 10, in particular. A coil 21 is formed on the surface of the second spherical semiconductor 20. A capacitor 31 is formed on the surface of the remaining spherical semiconductor 30.

Each two adjacent spherical semiconductors 10 and 20 (or 10 and 30) are combined to each other by means of an electrode terminal 50. The electrode terminal 50 mechanically bonds each two adjacent spherical semiconductors 10 and 20 (or 10 and 30) together, and electrically connects the electronic circuit of the spherical semiconductor 10 and the coil 21 or the capacitor 31 of the spherical semiconductor 20 or 30.

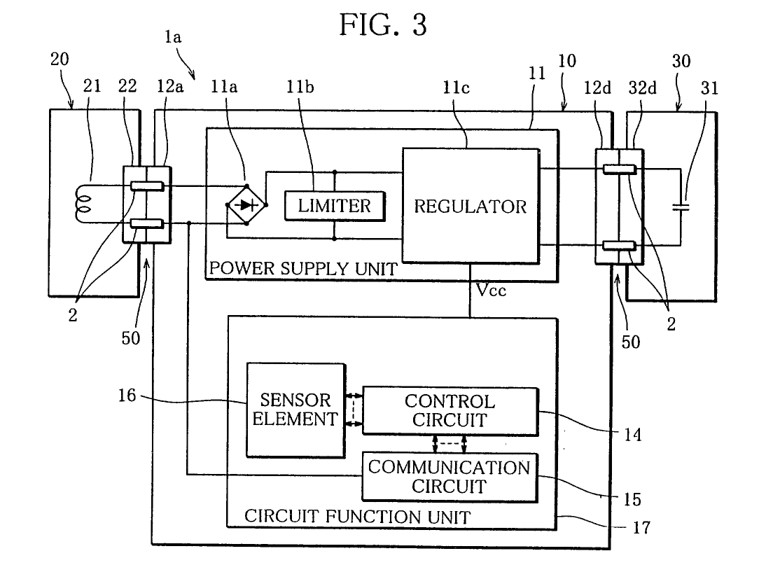

FIG. 2 specifically shows the spherical semiconductor 20, and FIG. 3 specifically shows the circuit configuration of the spherical semiconductor device 1a. As shown in FIG. 3, the spherical semiconductors 10, 20 and 30 have their respective junctions. The central spherical semiconductor 10, among the three spherical semiconductors 10, 20 and 30, has two junctions 12a and 12d, which are arranged symmetrically with respect to the center of the spherical semiconductor 10. The spherical semiconductors 20 and 30 at the opposite ends have junctions 22 and 32d, respectively.

The junctions 12a, 12d, 22 and 32d have a plurality of electrodes (hereinafter referred to as “pads”) 2 each. The pads 2 are formed on the surface of the spherical semiconductor 20, as shown in FIG. 2, by way of example. The pads 2 are arranged in a circle and at equal spaces in the circumferential direction of the circle on the spherical surface of each spherical semiconductor 10, 20 or 30. Each pad 2 is provided with a solder bump 3. All the solder bumps 3 extend in the same direction from their corresponding pads 2.

When the solder bumps 3 of each two adjacent spherical semiconductors 10 and 20 (or 10 and 30) are bonded together, they form the electrode terminal 50. The electrode terminal 50 electrically connects the coupled pads 2 and secures the mechanical bond between the adjacent spherical semiconductors.

The electrode terminal 50 is formed in the following steps of procedure. The electrode terminal 50 between the two spherical semiconductors 10 and 20, for example, is formed in a manner such that the pads 2 of the junctions 12a and 22 are electrically connected in a predetermined relation. Correspondingly, the spherical semiconductors 10 and 20 are positioned in a predetermined relation. When the electrode terminal 50 is formed, therefore, the spherical semiconductors 10 and 20 are positioned relatively to each other to establish the aforesaid relation of electrical connection and positional relation correctly. As this is done, the respective tips of the solder bumps 3 of the opposed pads 2 are butted against one another. In this state, the solder bumps 3 are heated, and the opposed pads 2 are soldered to one another. The electrode terminal 50 between the spherical semiconductors 10 and 30 is formed in the same manner.

The solder bumps 3, electrically conductive bonding members, need not always be provided on each of the adjacent spherical semiconductors. Therefore, the solder bumps 3 may be provided on the pads 2 of only one of the spherical semiconductors. Alternatively, if the pads of both the spherical semiconductors are flat, the opposed pads may be soldered to one another after the spherical semiconductors are positioned with respect to each other.

The number of the pads 2 of each junction should only be great enough for the transfer of signals between each two adjacent spherical semiconductors 10 and 20 (or 10 and 30). Possibly, however, all the junctions may be given a predetermined number of pads 2 without variation so that only those ones of the pads 2 which are essential to the transfer of the signals can be used selectively. In the case where each junction has a large number of pads 2, these pads 2 may be arranged in double or triple concentric circles. Alternatively, the pads 2 may be arranged in a semicircular arc or in any other suitable form.

As shown in FIG. 3, the electronic circuit that is formed on the central spherical semiconductor 10 includes a circuit function unit 17 and a power supply unit 11. The circuit function unit 17 fulfills its specific processing functions, and the power supply unit 11 serves to supply a given internal voltage Vcc to the circuit function unit 17. The coil 21 is formed on the surface of the adjacent spherical semiconductor 20. More specifically, the coil 21 is a wiring pattern of metal or the like that is formed in a spiral around the spherical semiconductor 20. The coil 21 serves to receive the RF carrier wave energy radiated from the external apparatus, generate alternating power, and supply the power to the power supply unit 11. The coil 21 also functions as a transmission antenna. Thus, data obtained by means of the circuit function unit 17 are transmitted from the coil 21 to an external apparatus (not shown). This process will be further described later.

A capacitor with a small capacity of tens of PF is formed on the surface of the spherical semiconductor 20. This capacitor can be connected in parallel with the coil 21, thereby constituting a resonance circuit. In this case, the capacitor may be formed in a region where the coil is not formed, or an insulating film may be formed between the capacitor and the coil. A transistor that is formed in a CMOS process, for example, has a problem that its performance is adversely affected by a thick insulating layer, if any, thereon. On the other hand, a passive element such as a capacitor has a character that its performance is hardly influenced by a thick insulating layer, if any, thereon.

Further, the capacitor 31 with a large capacity of hundreds of PF to hundreds of nF is formed on the surface of the spherical semiconductor 30. The capacitor 31 is formed over a wide area of the surface. The capacitor 31 is connected in parallel with the power supply unit 11 and serves to smooth the internal voltage Vcc the power supply unit 11 generates and to store its power energy. If the RF carrier wave energy received through the coil 21 is unstable, for example, the power energy stored in the capacitor 31 can compensate for required power energy for the operation of the circuit function unit 17 for a given time.

The following is a brief description of the reception of the RF carrier wave energy and the generation of the internal voltage Vcc by means of the power supply unit 11. The aforesaid external apparatus can radiate RF carrier wave energy based on long or medium waves or shortwaves of, e.g., hundreds of kHz. An optimum value is selected for the frequency of the RF carrier wave energy, depending on the reception efficiency of the coil 21 and restrictions on an IC process that constitutes a rectifier circuit 11a (mentioned later) and the like. The RF carrier wave energy may be based on unmodulated waves. A signal generator is a preferred example of the external apparatus.

Naturally, the external apparatus can also transmit control signals to the spherical semiconductors. In this case, the RF carrier wave energy can be modulated in accordance with digital data as the control signals to be transmitted. Further, the circuit function unit 17 includes a function that demodulates information on superposed digital data.

As shown in FIG. 3, the power supply unit 11 is provided with the rectifier circuit 11a, a limiter circuit 11b, and a regulator 11c, for example. The rectifier circuit 11a rectifies the alternating power that is generated by means of the coil 21 having received the RF carrier wave energy, and converts it into DC voltage. The limiter circuit 11b regulates the output voltage of the rectifier circuit 11a, thereby preventing generation of overvoltage. The regulator 11c stabilizes the output voltage of the rectifier circuit 11a and generates the internal voltage Vcc. The rectifier circuit 11a need not always be a full-wave rectifier, such as the one shown in FIG. 3, and may alternatively be a half-wave rectifier. Furnished with the regulator 11c, the spherical semiconductor device 1a need not be provided with any battery. Since the capacitor 31 can hold the received power as DC power, in particular, it can easily stabilize the internal voltage Vcc.

The circuit function unit 17 is composed of a control circuit 14, a communication circuit 15, and a sensor element 16. The sensor element 16 is an element that can detect a desired physical value of a temperature sensor or the like. The element 16 is formed in the manufacturing process of a semiconductor integrated circuit. The circuit function unit 17 is configured to deliver the physical value, detected by means of the sensor element 16, to the outside through the communication circuit 15. The control circuit 14 controls the output of the communication circuit 15. More specifically, the circuit function unit 17 is actuated when it is supplied with the internal voltage Vcc from the power supply unit 11. The control circuit 14 converts the physical value detected by means of the sensor element 16 into digital data and transmits it to the communication circuit 15. Based on the transmitted digital data, the communication circuit 15 changes the Q (quality factor) of the coil 21 that is formed on the spherical semiconductor 20.

Usually, the Q of a coil indicates the loss of the coil or the sharpness of the resonance circuit. It is to be desired that the Q should be as high as possible when the capacitor 31 is charged with electric power. The following two methods, for example, are used to change the Q. In one method, the communication circuit 15 is provided with a transistor that is connected to the coil 21. The transistor is turned on when the digital data from the control circuit 14 is 1, and is turned off when the digital data is 0. In the other method, the impedance of the power supply unit 11 is changed.

If the Q of the coil 21 is changed, a minute change is caused in an induction magnetic field that is generated by means of the RF carrier wave energy radiated from the external apparatus. The transmitted data can be grasped by externally monitoring this change. The greater the variation of the Q, the greater the change of the induction magnetic field is. The communication means is not limited to this configuration. The communication circuit 15 may alternatively transmit radio waves by utilizing the coil 21.

It is generally believed that the power receiving efficiency lowers and the power generated in the power supply unit 11 lessens correspondingly if the Q is lowered. In the case of the present invention, however, the capacitor 31 of the spherical semiconductor 30 is fully charged with electric power, so that necessary power for transmission can be secured satisfactorily. Even if the Q is made lower than in the prior art case so that the power receiving efficiency is lower, therefore, a satisfactory operating voltage can be secured according to the present invention. This advantage produces an effect such that the noise resistance according to the present invention can be improved considerably by making the change of the Q greater than in the prior art case to change the magnetic field more sharply. Since the change of the magnetic field can be intensified by making the Q lower than in the prior art case, moreover, the distance of external communication according to the present invention can be made longer than in the prior art case.

In a conventional spherical semiconductor device, a coil is formed over an electronic circuit with an insulating film between them. If the electronic circuit is thus coated with the insulating film, the film may possibly exert a bad influence upon the performance (properties) of the electronic circuit. Steps of coating the electronic circuit and forming the coil thereon are peculiar steps in a general manufacturing process for a spherical semiconductor device. Therefore, introduction of these steps used to make the entire spherical semiconductor device manufacturing method complicated.

In the spherical semiconductor device 1a, on the other hand, the spherical semiconductor 20 that has the coil 21 and the spherical semiconductor 10 that has the electronic circuit are constructed as separate spherical semiconductors, so that individual steps of the manufacturing process cannot be complicated. Since the electronic circuit is not coated with any insulating film, moreover, it can never be adversely affected thereby.

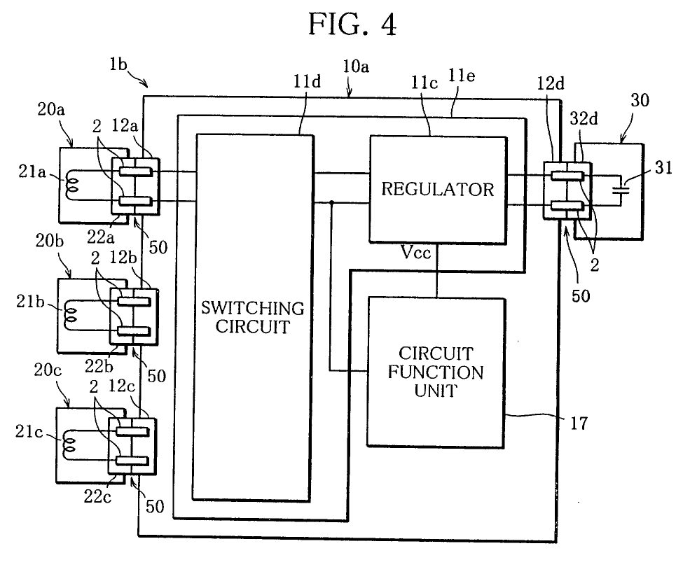

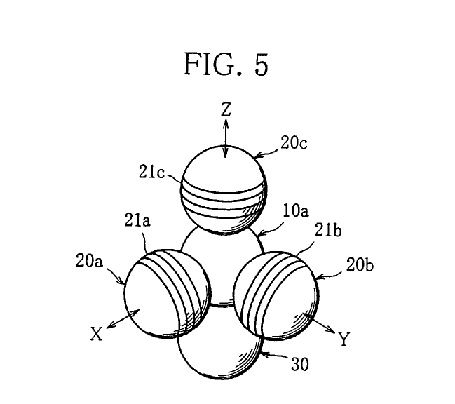

FIGS. 4 and 5 show a spherical semiconductor device 1b according to a second embodiment. In these drawings, like reference numerals refer to components that have the same functions as their counterparts according to the first embodiment. A description of the respective operations of those components is omitted.

As shown in FIGS. 4 and 5, the spherical semiconductor device 1b comprises five spherical semiconductors 10a, 20a, 20b, 20c and 30. The four spherical semiconductors 20a, 20b, 20c and 30 are combined together around the central spherical semiconductor 10a. An electronic circuit having specific processing functions is formed on the surface of the spherical semiconductor 10a. Coils 21a, 21b and 21c are formed on the three other spherical semiconductors 20a, 20b and 20c, respectively. The remaining spherical semiconductor 30 is constructed in the same manner as the one according to the first embodiment.

Further, the central spherical semiconductor 10a has four junctions 12a, 12b, 12c and 12d. These junctions 12a, 12b, 12c and 12d serve to combine the four other spherical semiconductors 20a, 20b, 20c and 30. The junction 12c and the junction 12d that combines the spherical semiconductor 30 and the spherical semiconductor 10a are situated in positions symmetrical with respect to the center of the spherical semiconductor 10a.

The spherical semiconductor 20a has a junction 22a for combination with the spherical semiconductor 10a. The spherical semiconductors 20b and 20c have junctions 22b and 22c, respectively. These junctions are formed on the respective surfaces of their corresponding spherical semiconductors.

In this second embodiment, as in the case of the first embodiment, each pair of opposed junctions are connected together in accordance with a predetermined relation of electrical connection and positional relation between each two spherical semiconductors to be connected. If each two junctions are connected in correct combination, an electrode terminal 50 is formed there.

The three spherical semiconductors 20a, 20b and 20c that have a coil each are connected around the central spherical semiconductor 10a in a manner such that the respective maximum flux directions of the coils 21a, 21b and 21c on their respective surfaces are perpendicular to one another. For example, the coils 21a, 21b and 21c have their maximum flux directions corresponding to the X-, Y-, and Z-axis directions, respectively (see FIG. 5).

As shown in FIG. 4, the central spherical semiconductor 10a has an electronic circuit formed on its surface. This electronic circuit includes a specific circuit function unit 17 and a power supply unit 11e. The power supply unit 11e has a switching circuit lid and a regulator 11c.

Usually, RF carrier wave energy radiated from an external apparatus has a fixed maximum flux direction. If the maximum flux direction of a certain coil is coincident with this fixed maximum flux direction, the coil can receive the RF carrier wave energy most efficiently as alternating power. If the maximum flux direction of the coil is not coincident with that of the RF carrier wave energy, on the other hand, the RF carrier wave energy the coil can receive as the alternating power lessens.

In the spherical semiconductor device 1b that has the three coils 21a, 21b and 21c, the power supply unit 11e of the spherical semiconductor 10a has the switching circuit 11d and the regulator 11c. The switching circuit 11d further has three rectifier circuits and three limiter circuits, which are configured to correspond to outputs from the three coils 21a, 21b and 21c, individually. The switching circuit 11d selects the rectifier circuit that provides the highest alternating power, out of the three rectifier circuits corresponding individually to the outputs from the coils 21a, 21b and 21c, and switches the circuit to supply output form the selected rectifier circuit to the regulator 11c.

The power supply unit 11e may further have a detector circuit. In this case, all the three coils 21a, 21b and 21c are connected to the power supply unit 11e, and the detector circuit detects the coil that receives the highest alternating power, out of the three coils. The detected coil is connected to one of the rectifier circuits as the switching circuit 11d switches the target to which the coil is connected.

Alternatively, the three coils may be connected in series with one another. In this case, the coils are connected directly to one of the rectifier circuits without the interposition of any switching circuit.

The aforesaid rectifier circuit is connected to the regulator 11c. The regulator 11c stabilizes voltage delivered from the rectifier circuit and generates an internal voltage Vcc. The internal voltage Vcc is utilized for the driven of the circuit function unit 17. A capacitor 31, which is connected to the regulator 11c, can hold received electric power as DC power, as in the case of the rectifier circuit 11a according to the first embodiment.

In the spherical semiconductor device 1b, the three coils on the three spherical semiconductors 20a, 20b and 20c are arranged at right angles to one another, so that at least one of the coils can satisfactorily receive the RF carrier wave energy without regard to the attitude of the device 1b. Thus, the spherical semiconductor device 1b can produce the following effects besides the effects of the foregoing spherical semiconductor device 1a. First, the spherical semiconductor device 1b can satisfactorily receive the alternating power from the RF carrier wave energy without depending on the maximum flux direction of the RF carrier wave energy. Further, the spherical semiconductor device 1b can satisfactorily supply DC power that actuates the electronic circuit, so that noncontact data transfer can be achieved successfully.

The spherical semiconductor device 1b has an additional effect. More specifically, the spherical semiconductor 30 that is connected to the spherical semiconductor 10a can maintain the power received by means of the capacitor 31 for a longer period of time. If the communication circuit 15 changes the Q of the coil in order to transmit data, therefore, the DC power that actuates the electronic circuit can be supplied more satisfactorily, so that the noncontact data transfer can be achieved more successfully.

The three coils need not be arranged exactly at right angles to one another. It is necessary only that the three coils be arranged substantially at right angles to one another so that the RF carrier wave energy can be received without doing any actual harm to the operation of the spherical semiconductor device 1b.

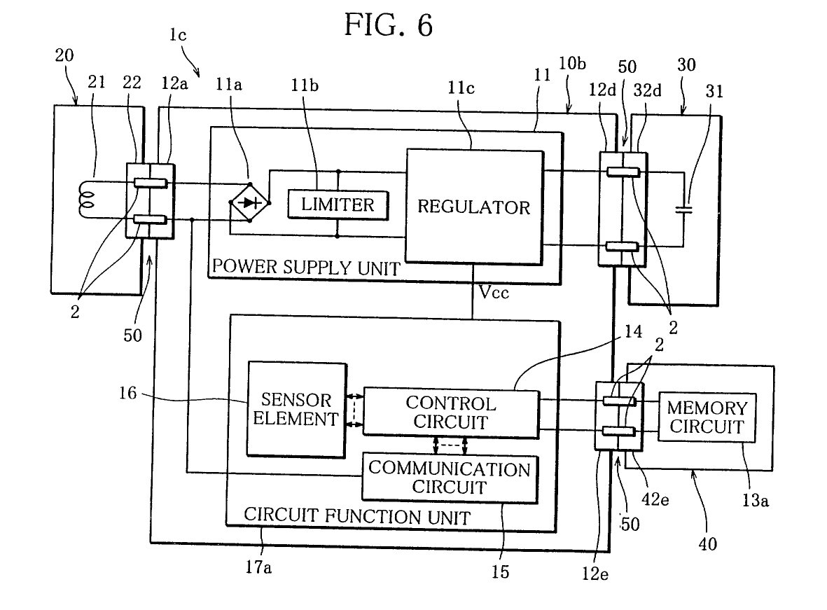

FIG. 6 shows a spherical semiconductor device 1c according to a third embodiment. In this drawing, like reference numerals refer to components that have the same functions as their counterparts according to the first embodiment. A description of the respective operations of those components is emitted.

The spherical semiconductor device 1c comprises four spherical semiconductors 10b, 20, 30 and 40. The three spherical semiconductors 10b, 20 and 30 are connected in the same manner as the three spherical semiconductors 10, 20 and 30 according to the first embodiment. The spherical semiconductor 10b of the present embodiment differs from the foregoing spherical semiconductor 10 in that it further has a junction 12e on its surface. The junction 12e is formed in the same manner as the other junctions, and pads 2 of the junction 12e are connected electrically to a circuit function unit 17a. The spherical semiconductor 40 includes a junction 42e having a plurality of pads 2 that are connected electrically to a memory circuit 13a. The junctions 12e and 42e, like the other pairs of junctions, are connected to each other. Likewise, an electrode terminal 50 is formed if each two junctions are connected.

The spherical semiconductor device 1c constructed in this manner, like the spherical semiconductor device 1a of the first embodiment, is actuated in the presence of RF carrier wave energy radiated from an external apparatus, and transfers data to and from the external apparatus in a noncontact manner.

Preferably, a memory formed in the memory circuit 13a should be a nonvolatile memory that can hold data even when the reception of the RF carrier wave energy is interrupted. The memory circuit 13a may include, besides the memory, a circuit for controlling access to the memory. Alternatively, the memory circuit 13a of the spherical semiconductor 40 may include the memory only. In this case, the circuit for controlling access to the memory is formed on the spherical semiconductor 10b.

In the spherical semiconductor 1c, the specifications of the electronic circuit can be easily changed without lowering the productivity of the spherical semiconductors by modifying the spherical semiconductor 40. In the case where the spherical semiconductor 40 has a memory circuit, for example, various data can be transferred to and from an electronic circuit by changing the specifications of the spherical semiconductor 40.

A conventional spherical semiconductor device has a problem that its manufacturing process becomes complicated if the specifications of its memory circuit are changed. More specifically, changing the specifications of the memory circuit requires modification of the design of the electronic circuit itself or introduction of another manufacturing process. In order to change the specifications of the memory circuit, therefore, the manufacturing process and other particulars must be reviewed.

Since the specifications of the spherical semiconductor 10b in the spherical semiconductor device 1c need not be changed, on the other hand, the manufacturing process for the device cannot be complicated. The spherical semiconductor device 1b has an advantage in easily coping with the change of the memory capacity by modifying the spherical semiconductor 40.

Even if the manufacturing processes for the spherical semiconductors 10b and 40 are considerably different, moreover, the spherical semiconductor device 1b can be manufactured by only bonding the two spherical semiconductors 10b and 40 after the termination of the individual processes. This advantage produces a great effect in the case where the spherical semiconductor 40 is formed in a manufacturing process for a special memory semiconductor such as an EEPROM or ferrodielectric substance memory and if the spherical semiconductor 10b is formed by a general process such as a CMOS process, in particular. For the conventional spherical semiconductor device, two or more different manufacturing processes must be applied to the manufacture of each spherical semiconductor, so that it is very hard to enjoy conformity between the two processes. For the spherical semiconductor device 1b, on the other hand, it is necessary only that the two spherical semiconductors 10b and 40a be connected to each other after the termination of their manufacturing processes despite the difference between the processes. Thus, the spherical semiconductor device 1c can be formed with ease.

The change of the specifications of the spherical semiconductor 40 alone enjoys a high degree of freedom. If the sensor element is formed on the surface of the spherical semiconductor 40, therefore, the spherical semiconductor device 1b having various sensor elements can be easily obtained by changing the specifications of the spherical semiconductor 40. In this case, the specifications of the spherical semiconductor 10b need not be changed either, so that the productivity of the spherical semiconductor device 1b cannot be ruined.

For example, a sensor element can be formed on the surface of the spherical semiconductor 40 by using a special process such as anisotropic etching. In this case, the desired spherical semiconductor device 1c can be obtained by previously forming an electronic circuit for processing output signals from the sensor on the surface of the spherical semiconductor 10b and then only bonding the two spherical semiconductors 10b and 40 to each other. In this case, the spherical semiconductor device 1b can be also easily manufactured despite the difference between the processes.

Further, a high-value resistor of several megaohms can be formed on the surface of the spherical semiconductor 40. In this case, the higher its resistance value, the wider the area of the surface of the spherical semiconductor 40 occupied by the diffused resistor formed on the surface of the spherical semiconductor 40 is. Nevertheless, the configuration of the electronic circuit of the spherical semiconductor 10b cannot be restricted by the formation of the high-value resistor. In the conventional spherical semiconductor device, an electronic circuit and a high-value resistor are jointly formed on the surface of one spherical semiconductor. If the high-value resistor occupies too wide an area, therefore, restrictions are imposed on the configuration of the electronic circuit. Conventionally, therefore, the restrictions on the configuration of the electronic circuit can be avoided only by increasing the diameter of the spherical semiconductor. If the resistance value of the high-value resistor of the spherical semiconductor device 1b is increased, on the other hand, the configuration of the electronic circuit is subject to no restrictions at all.

Thus, the spherical semiconductor device having a large-capacity capacitor, memory circuit, sensor element, and/or high-value resistor formed on a spherical semiconductor that is different from the one on which the electronic circuit is formed can be easily manufactured without regard to the difference between the manufacturing processes for the individual spherical semiconductors. In consequence, the period of development of the spherical semiconductor device can be shortened, and its reliability can be improved.

In general, a passive element occupies a wide area on the surface of a spherical semiconductor. Since this passive element is formed on a spherical semiconductor that is different from one on which an electronic circuit is formed, however, each spherical semiconductor can be made smaller than in the case where the two elements are formed on one and the same spherical semiconductor. Besides, restrictions on the integration degree of a transistor and other elements that are formed on the electronic circuit can be eased.

The present invention is not limited to the embodiment described above. The spherical semiconductor device is provided with the three coils in order to fulfill the function to receive the highest alternating power from the RF carrier wave energy without depending on the relation between its posture and the maximum flux direction of the RF carrier wave energy. By fulfilling this function, the spherical semiconductor device can maintain its satisfactory operation. Thus, it is necessary only that the angle of intersection between the respective maximum flux directions of the coils and the coil connection be arranged so that the function can be fulfilled.

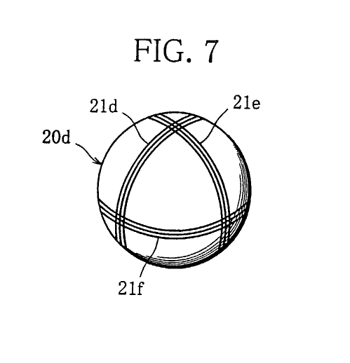

As shown in FIG. 7, a spherical semiconductor 20d that has coils may be designed so that three coils 21d, 21e and 21f having their respective maximum flux directions perpendicular to one another are formed on its same surface.

Even in the case where a coil and an electronic circuit are formed on the surface of the same spherical semiconductor, the operation of the spherical semiconductor device can be maintained satisfactorily by obtaining DC power from alternating power received by means of the coil and holding it in the capacitor 31 only if the spherical semiconductor 30 is connected to this spherical semiconductor.

In the case where three spherical semiconductors having their respective coils are connected to the central spherical semiconductor, the spherical semiconductor device may be also constructed so that a spherical semiconductor having a memory circuit or sensor element is connected to the central spherical semiconductor. Further, this spherical semiconductor device may be provided with another spherical semiconductor that has a capacitor.

What is claimed is:

1. A spherical semiconductor device containing two or more spherical semiconductors combined together, comprising:
an electronic circuit formed on the surface of one of said spherical semiconductors;
a coil formed on the surface of another one of said spherical semiconductors;
electrode terminals formed individually on the respective surfaces of said two spherical semiconductors and capable of electrically connecting said coil and said electronic circuit to each other and bonding said two spherical semiconductors to each other; and
a power supply included in said electronic circuit and capable of receiving RF carrier wave radiated from an external apparatus through said coil and rectifying the current induced in said coil to produce a voltage for the actuation of said electronic circuit.

2. The spherical semiconductor device according to claim 1, wherein said another one of said spherical semiconductors has three coils on the surface thereof, said three coils being oriented orthogonally from one another.

3. The spherical semiconductor device according to claim 1, wherein said one semiconductor having said electronic circuit is combined with three other spherical semiconductors having a coil each, said three spherical semiconductors being situated so that the respective coils thereof extend orthogonally from one another.

4. A spherical semiconductor device containing two or more spherical semiconductors combined together, comprising:
an electronic circuit formed on the surface of one of said spherical semiconductors and having specific processing functions;
a circuit element formed on the surface of another one of said spherical semiconductors and having at least one of the respective functions of a capacitor, resistor, sensor, and memory; and
electrode terminals formed individually on the respective surfaces of said two spherical semiconductors and capable of electrically connecting said electronic circuit and said circuit element to each other and bonding said two spherical semiconductors to each other.

5. The spherical semiconductor device according to claim 4, wherein said one spherical semiconductor having said electronic circuit is bonded to two or more other spherical semiconductors having the respective circuit elements thereof with different functions.
